(19) United States
(12) Patent Application Publication
(10) Pub. No.: US 2025/0004362 A1
(43) Pub. Date: Jan. 2, 2025

(54) PELLICLE MEMBRANE

(71) Applicant: ASML NETHERLANDS B.V., Veldhoven (NL)

(72) Inventors: Franciscus Theodorus AGRICOLA, Waalre (NL); Lourdes FERRE LLIN, Geldrop (NL); Dennis DE GRAAF, Waalre (NL); Chaitanya Krishna ANDE, Eindhoven (NL); Inci DONMEZ NOYAN, Eindhoven (NL); Fai Tong SI, Veldhoven (NL); Ties Wouter VAN DER WOORD, Eindhoven (NL); Anne-Sophie ROLLIER, Bromont (CA); Maxime BIRON, Bromont (CA); Adrianus Johannes Maria GIESBERS, Vlijmen (NL)

(73) Assignee: ASML NETHERLANDS B.V., Veldhoven (NL)

(21) Appl. No.: 18/293,851

(22) PCT Filed: Jul. 28, 2022
(86) PCT No.: PCT/EP2022/071251

§ 371 Date: Jan. 31, 2024

(30) Foreign Application Priority Data
Aug. 26, 2021 (EP) 21193346.0

(51) Int. Cl. G03F 1/62; G03F 1/24

(52) U.S. Cl. CPC G03F 1/62; G03F 1/24

(57) ABSTRACT

A pellicle membrane for a lithographic apparatus, wherein the pellicle membrane includes metal silicide and a reinforcing network. The reinforcing network can be located between metal silicide layers. The reinforcing network can be irregular. The reinforcing network includes windows with a maximum dimension of up to 20 microns. The reinforcing network includes windows having an average size of at least 5 microns.

### CROSS-REFERENCE TO RELATED APPLICATIONS

This application claims priority of EP application 21193346.0 which was filed on 26 Aug. 2021 and which is incorporated herein in its entirety by reference.

### FIELD

The present invention relates to a pellicle membrane. The present invention has particular, but not exclusive, use in connection with EUV lithographic apparatus and EUV lithographic tools. The present invention also relates to pellicle assemblies and lithographic apparatus comprising such assemblies.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

A pattern may be imparted to a radiation beam in a lithographic apparatus using a patterning device (e.g. a mask or reticle). Radiation is provided through or reflected off the patterning device to form an image on a substrate. Contamination on the surface of the patterning device can cause manufacturing defects on the substrate. A membrane assembly, also referred to as a pellicle, may be provided to protect the patterning device from airborne particles and other forms of contamination.

Pellicles may also be provided for protecting optical components other than patterning devices. Pellicles may also be used to provide a passage for lithographic radiation between regions of the lithography apparatus which are sealed from one another. Pellicles may also be used as filters, such as spectral purity filters or as part of a dynamic gas lock of a lithographic apparatus.

The use of pellicles in lithography is well-known and well-established. A pellicle in a lithographic apparatus is a membrane (also referred to as a pellicle membrane) which is located away from the patterning device and is out of the focal plane of a lithographic apparatus in use. As the pellicle is out of the focal plane of the lithographic apparatus, contamination particles which land on the pellicle are out of focus in the lithographic apparatus. Consequently, images of the contamination particles are not projected onto the substrate. If the pellicle were not present, then a contamination particle which landed on the patterning device would be projected onto the substrate and would introduce a defect into the projected pattern.

A mask assembly may include the pellicle which protects a patterning device (e.g. a mask) from particle contamination. The pellicle may be supported by a pellicle frame, forming a pellicle assembly or membrane assembly. The pellicle may be attached to the frame, for example, by gluing or otherwise attaching a pellicle border region to the frame. The frame may be permanently or releasably attached to a patterning device. The frame may also be known as a border.

It is desirable to provide a pellicle membrane and/or a pellicle assembly, which addresses a problem associated with the prior art.

### SUMMARY

According to a first aspect of the invention there is provided a pellicle membrane for a lithographic apparatus, wherein the pellicle membrane comprises metal silicide and a reinforcing network.

Advantageously, the reinforcing network strengthens the pellicle, whilst at the same time causing only a small reduction of the transmission of the pellicle. Advantageously, because outer surfaces of the pellicle are metal silicide, the behaviour of the surface of the pellicle when exposed to conditions such as EUV radiation is unaffected by the reinforcing network.

The reinforcing network may be located between metal silicide layers.

Advantageously, because outer surfaces of the pellicle are metal silicide, the behaviour of the surface of the pellicle when exposed to conditions such as EUV radiation is unaffected by the reinforcing network.

The reinforcing network may be irregular.

The reinforcing network may include windows with a maximum dimension of up to 20 microns.

The reinforcing network may include windows having an average size of at least 5 microns.

The reinforcing network, excluding windows, may have an area which is up to 10% of the pellicle.

The reinforcing network may be formed from nanotubes.

The nanotubes may be carbon nanotubes.

The nanotubes may be coated.

An additional layer may be provided between the reinforcing network and at least one of the metal silicide layers.

The at least one additional layer may be a metallic layer.

The metal silicide may be nitridated metal silicide.

According to a second aspect of the invention there is provided a pellicle assembly comprising the pellicle membrane of the first aspect of the invention, and a frame, the pellicle membrane being supported by the frame.

According to a third aspect of the invention there is provided a pellicle assembly comprising a pellicle membrane supported by a frame, wherein the pellicle membrane does not extend fully to an outer edge of the frame.

Advantageously, this arrangement may provide improved contrast when an imaging system looks at the pellicle assembly (from a side of the pellicle which is opposite from a side on which the frame is provided).

A border stack comprising a plurality of may be is provided between the frame and the pellicle membrane. At least part of the border stack may extend not fully to an outer edge of the frame.

Advantageously, this arrangement may provide further improved contrast when an imaging system looks at the pellicle assembly (from a side of the pellicle which is opposite from a side on which the frame is provided).

An outer edge of the pellicle membrane may be provided with a shape for use as an alignment mark. An outer edge of at least part of the border stack may be provided with a shape for use as an alignment mark.

The pellicle membrane and border stack may be generally rectangular. The shape may be provided at at least one corner of the pellicle membrane and optionally at least part of the border stack.

The shape may be provided at each corner of the pellicle membrane and optionally at least part of the border stack.

The shape may comprise two projections which extend from the corner.

The two projections may extend perpendicularly to each other.

At least one layer of the border stack may extend fully to the outer edge of the frame.

The border stack may comprise an oxide layer located below the pellicle membrane and above a Silicon-based layer of the border stack.

The oxide layer may have a thickness which is selected to contribute to a desired contrast ratio between a combination of the pellicle membrane and pellicle frame and a combination of the pellicle membrane and a patterning device.

The oxide layer may have a thickness which is selected to contribute to a desired contrast ratio between a combination of the pellicle membrane and the border stack frame and an outer portion of the frame where at least part of the border stack is not present.

According to a fourth aspect of the invention there is provided a pellicle assembly comprising the pellicle membrane of the first aspect, and further comprising a frame which supports the pellicle membrane, the frame comprising a base and a border stack, wherein the border stack comprises an oxide layer located below the pellicle membrane and above a Silicon-based layer of the border stack.

The oxide layer may have a thickness which is selected to contribute to a desired contrast ratio between a combination of the pellicle membrane and pellicle frame and a combination of the pellicle membrane and a patterning device.

The desired contrast ratio may be 0.1 or more.

According to a fifth aspect of the invention there is provided a mask assembly comprising the pellicle of a preceding aspect, and further comprising a lithographic mask, wherein the border stack and pellicle membrane have a combined reflectivity which is different to a combined reflectivity of the pellicle membrane and the lithographic mask.

The combined reflectivity of the border stack and pellicle membrane versus the combined reflectivity of the pellicle membrane and lithographic mask may provide a contrast ratio of 0.1 or more.

According to a sixth aspect of the invention there is provided a method of fabricating a pellicle assembly, the method comprising providing a base, providing a plurality of sacrificial layers on the base, providing a first metal silicide layer on an uppermost sacrificial layer, providing a reinforcing network on the first metal silicide layer, and providing a second metal silicide layer on the reinforcing network.

A metallic layer may be provided on top of the reinforcing network before the second metal silicide layer is provided.

The reinforcing network may be formed from carbon nanotubes.

According to a seventh aspect of the invention there is provided a lithographic apparatus comprising a pellicle membrane, pellicle assembly, or mask assembly of a preceding aspect.

The features described in respect of any of the aspects may be combined with the features described in respect of any of the other aspects of the present invention.

The present invention will now be described with reference to an EUV lithography apparatus. However, it will be appreciated that the present invention is not limited to EUV lithography and may be suitable for other types of lithography.

### BRIEF DESCRIPTION OF THE DRAWINGS

Embodiments of the invention will now be described, by way of example only, with reference to the accompanying schematic drawings, in which:

FIG. 1 schematically depicts a lithographic system comprising a lithographic apparatus and a radiation source;

FIG. 2 schematically depicts a pellicle assembly;

FIGS. 3A and 3B schematically depict a pellicle assembly according to an embodiment of the invention;

FIGS. 4A and 4B schematically depict a pellicle assembly according to a further embodiment of the invention;

FIGS. 5A and 5B schematically depict a pellicle assembly according to a still further embodiment of the invention;

FIG. 6 is a graph showing how a contrast ratio varies as a function of material thickness of a border stack of a frame of the pellicle assembly; and

FIG. 7 schematically illustrates stages of manufacture of a pellicle membrane and pellicle assembly according to an embodiment of the present invention.

### DETAILED DESCRIPTION

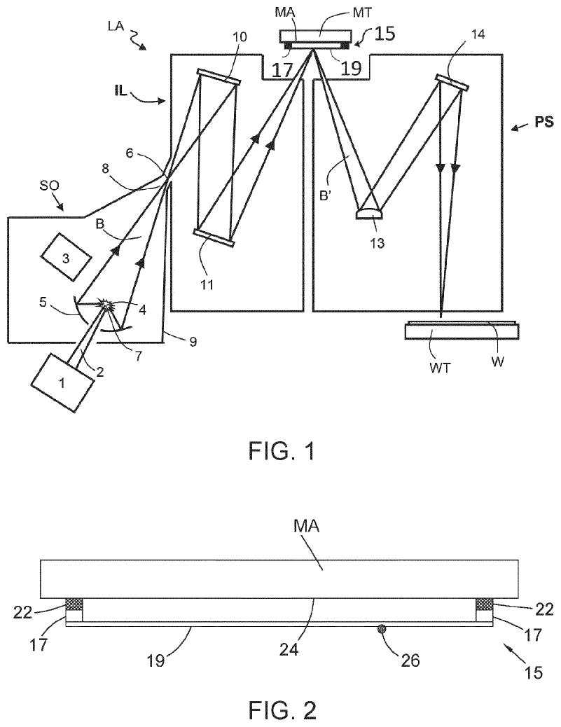

FIG. 1 shows a lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated.

A pellicle assembly 15 is depicted in the path of the radiation to protect the patterning device MA. The pellicle assembly 15 comprises a pellicle membrane 19 and a frame 17 which supports the pellicle membrane 19. The frame 17 may be referred to as a border. The pellicle membrane 19 comprises a thin film that is substantially transparent to EUV radiation (although it will absorb a small amount of EUV radiation). The pellicle membrane 19 acts to protect the patterning device MA from particle contamination. The pellicle membrane 19 may be referred to simply as a pellicle. It will be appreciated that the pellicle assembly 15 may be located in any required position and may be used to protect any elements of the lithographic apparatus e.g. one or more of the mirrors in the lithographic apparatus.

Whilst efforts may be made to maintain a clean environment inside the lithographic apparatus LA, particles may still be present inside the lithographic apparatus LA. In the absence of a pellicle 19, particles may be deposited onto the patterning device MA. Particles on the patterning device MA may disadvantageously affect the pattern that is imparted to the radiation beam B and therefore the pattern that is transferred to the substrate W. The pellicle 19 provides a barrier between the patterning device MA and the environment in the lithographic apparatus LA in order to prevent particles from being deposited on the patterning device MA.

In use, the pellicle 19 is positioned at a distance from the patterning device MA that is sufficient that any particles that are incident upon the surface of the pellicle 19 are not in the focal plane of the radiation beam B. This separation between the pellicle 19 and the patterning device MA, acts to reduce the extent to which any particles on the surface of the pellicle 19 impart a pattern to the radiation beam B. It will be appreciated that where a particle is present in the beam of radiation B, but at a position that is not in a focal plane of the beam of radiation B (i.e., not at the surface of the patterning device MA), then any image of the particle will not be in focus at the surface of the substrate W. In some embodiments, the separation between the pellicle 19 and the patterning device MA may, for example, be between 2 mm and 3 mm (e.g. around 2.5 mm). In some embodiments, a separation between the pellicle 19 and the patterning device may be adjustable.

After the generation of the patterned EUV radiation beam B′, the projection system PS is configured to project the patterned EUV radiation beam B′ onto the substrate W. For that purpose, the projection system PS may comprise a plurality of mirrors 13,14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13, 14 in FIG. 1, the projection system PS may include a different number of mirrors (e.g., six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e. a small amount of gas (e.g. hydrogen) at a pressure well below atmospheric pressure, may be provided in the radiation source SO, in the illumination system IL, and/or in the projection system PS.

The radiation source SO shown in FIG. 1 is, for example, of a type which may be referred to as a laser produced plasma (LPP) source. A laser system 1, which may, for example, include a CO₂ laser, is arranged to deposit energy via a laser beam 2 into a fuel, such as tin (Sn) which is provided from, e.g., a fuel emitter 3. Although tin is referred to in the following description, any suitable fuel may be used. The fuel may, for example, be in liquid form, and may, for example, be a metal or alloy. The fuel emitter 3 may comprise a nozzle configured to direct tin, e.g. in the form of droplets, along a trajectory towards a plasma formation region 4. The laser beam 2 is incident upon the tin at the plasma formation region 4. The deposition of laser energy into the tin creates a tin plasma 7 at the plasma formation region 4. Radiation, including EUV radiation, is emitted from the plasma 7 during de-excitation and recombination of electrons with ions of the plasma.

The EUV radiation from the plasma is collected and focused by a collector 5. Collector 5 comprises, for example, a near-normal incidence radiation collector 5 (sometimes referred to more generally as a normal-incidence radiation collector). The collector 5 may have a multilayer mirror structure which is arranged to reflect EUV radiation (e.g., EUV radiation having a desired wavelength such as 13.5 nm). The collector 5 may have an ellipsoidal configuration, having two focal points. A first one of the focal points may be at the plasma formation region 4, and a second one of the focal points may be at an intermediate focus 6, as discussed below.

The laser system 1 may be spatially separated from the radiation source SO. Where this is the case, the laser beam 2 may be passed from the laser system 1 to the radiation source SO with the aid of a beam delivery system (not shown) comprising, for example, suitable directing mirrors and/or a beam expander, and/or other optics. The laser system 1, the radiation source SO and the beam delivery system may together be considered to be a radiation system.

Radiation that is reflected by the collector 5 forms the EUV radiation beam B. The EUV radiation beam B is focused at intermediate focus 6 to form an image at the intermediate focus 6 of the plasma present at the plasma formation region 4. The image at the intermediate focus 6 acts as a virtual radiation source for the illumination system IL. The radiation source SO is arranged such that the intermediate focus 6 is located at or near to an opening 8 in an enclosing structure 9 of the radiation source SO.

Although FIG. 1 depicts the radiation source SO as a laser produced plasma (LPP) source, any suitable source such as a discharge produced plasma (DPP) source or a free electron laser (FEL) may be used to generate EUV radiation.

FIG. 2 is a schematic illustration of the pellicle assembly 15 and the patterning device MA in cross-section and in more detail. The patterning device MA has a patterned surface 24. The pellicle frame 17 (or ‘border’) supports the pellicle 19 around a perimeter portion of the pellicle 19. The pellicle frame 17 may include an attachment mechanism 22 configured to allow the pellicle frame 17 to be removably attachable to the patterning device MA (i.e. to allow the pellicle frame 17 to be attachable to and detachable from the patterning device MA). The attachment mechanism 22 is configured to engage with an attachment feature (not shown) provided on the patterning device MA. The attachment feature may, for example, be a protrusion which extends from the patterning device MA. The attachment mechanism 22 may, for example, comprise a locking member which engages with the protrusion and secures the pellicle frame 17 to the patterning device MA. The pellicle frame 17 may be attached to the mask via a further pellicle frame. A plurality of attachment mechanisms and associated attachment features may be provided. The attachment mechanisms may be distributed around the pellicle frame 17 (e.g. two on one side of the frame and two on an opposite side of the frame). Associated attachment features may be distributed around the perimeter of the patterning device MA. It should be understood that any other attachment mechanism or positioning method may be used to position the pellicle membrane 19 in the desired position.

A contamination particle 26 is schematically shown in FIG. 2. The contamination particle 26 was incident upon the pellicle 19 and is held by the pellicle 19. The pellicle 19 holds the contamination particle sufficiently far from the patterned surface 24 of the mask MA that it is not imaged onto substrates by the lithographic apparatus LA. A pellicle assembly according to an embodiment of the invention may allow a mask pattern (on the patterning device) to be provided which remains substantially defect free during use (the mask pattern is protected from contamination by the pellicle).

The pellicle assembly 15 may be constructed by depositing the pellicle 19 directly on top of a substrate which is to provide the frame 17. The substrate may be, for example, a silicon wafer or an SOI wafer. After deposition of a film defining the pellicle 19, the substrate may be selectively back-etched to remove a central portion of the substrate and leave only an outer perimeter to form the frame 17 to support the pellicle 19. An example of the fabrication process is discussed further below.

The pellicle 19 may for example be formed from metal silicide or doped metal silicide. Doped metal silicide may be described by the formula Mₓ(Si)_{y}D_{z}, where M denotes a metal, Si denotes silicon, and D denotes a dopant. The subscripts x, y and z denote the relative ratios of M, Si and D respectively.

The metal M may be one of a range of metals. For example, the metal may be selected from the group comprising Ce, Pr, Sc, Eu, Nd, Ti, V, Cr, Zr, Nb, Mo, Ru, Rh, La, Y, and Be. Of this group, the preferred metals are zirconium, molybdenum or beryllium. Molybdenum is the most preferred.

The dopant D may be one of a range of dopants. For example, the dopant may be oxygen, carbon, boron or nitrogen. Of these, the preferred dopant is nitrogen.

Of particular interest is nitridated molybdenum silicide (MoSiN) and molybdenum silicide (MoSi). The relative ratios of molybdenum, silicon and, optionally, nitrogen may be altered. Embodiments of the invention may comprise any metal silicide or doped metal silicide.

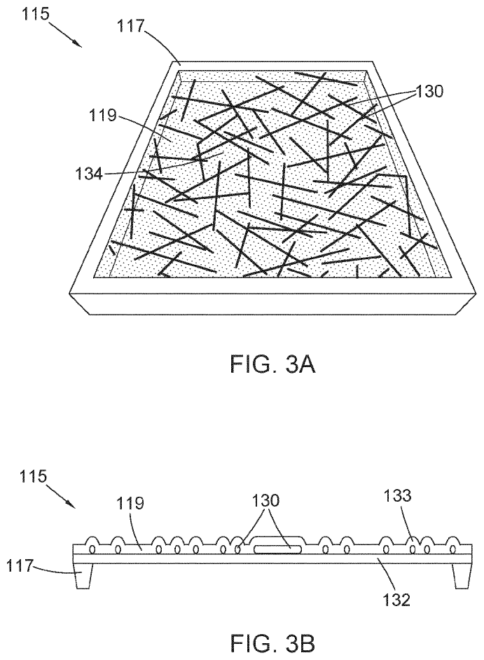

FIGS. 3A and 3B schematically depict a pellicle assembly 115 according to an embodiment of the invention. The pellicle assembly 115 is depicted in perspective view in FIG. 3A and in cross-section in FIG. 3B. The pellicle assembly 115 comprises a pellicle membrane 119 and a frame 117 which supports the pellicle membrane. The frame 117 may be referred to as a border.

The pellicle membrane 119 comprises carbon nanotubes 130 located between two metal silicide layers 132,133. The metal silicide layers may for example be MoSiN. Referring to FIG. 3B, it may be seen that a lower layer 132 of metal silicide is substantially flat whereas an upper layer 133 of metal silicide includes ridges where it passes over the carbon nanotubes 130. This is a result of the manner in which the pellicle membrane 119 is fabricated, as is discussed further below.

The carbon nanotubes 130 are not provided in an ordered arrangement. Instead they are provided in a disordered arrangement (e.g. a random arrangement). As is schematically depicted, the carbon nanotubes 130 intersect one another. These intersections establish areas of the pellicle membrane 119 which are each fully surrounded by carbon nanotubes 130. An example of a fully surrounded area 134 of the pellicle membrane 119 is labelled in FIG. 3A. In practice, there many more carbon nanotubes 130 are present than is schematically depicted, and thus many more fully surrounded areas are present than is schematically depicted. The carbon nanotubes 130 form a reinforcing network which acts to strengthen the pellicle membrane 119. The reinforcing network formed by the carbon nanotubes 130 establishes a patchwork of fully surrounded areas of the pellicle membrane 119, i.e. areas of the pellicle membrane which are fully surrounded by carbon nanotubes 130.

The term “intersect” is not intended to mean that one carbon nanotube penetrates and passes through another carbon nanotube. Instead, one carbon nanotube crosses over another carbon nanotube, e.g. with a first carbon nanotube lying on top of the second carbon nanotube at the point where they cross.

Because the pellicle membrane 119 is made up of areas that are fully surrounded by carbon nanotubes (e.g. such as labelled area 134), tearing of the pellicle along a substantial length or width of the pellicle is prevented or inhibited. A defect in the pellicle or some contamination may cause a hole to be formed in the pellicle. In a prior art pellicle, that hole could propagate as a tear extending across a substantial proportion of the pellicle. Propagation of the tear may be caused by the rapid acceleration and deceleration of the pellicle which will occur during operation of the lithographic apparatus LA. Advantageously, the carbon nanotubes 130 are sufficiently strong that a hole in the pellicle will not propagate across a carbon nanotube. This prevents a tear becoming established which extends across a substantial portion of the pellicle membrane 119. Taking fully surrounded area 134 as an example, if a hole were to form in that area, the hole may propagate outwards as far as the carbon nanotubes 130 which surround that area. The hole would however not propagate any further. The size of the hole is thereby limited to the size of the fully surrounded area 134. A fully surrounded area may be referred to as a fully enclosed area or a window.

The size of the fully surrounded areas of the pellicle membrane 119 is determined by the density of carbon nanotubes provided on the pellicle membrane 119 (a higher density of carbon nanotubes will provide smaller fully surrounded areas). Thus, to provide small enclosed pellicle areas it may be considered desirable to provide a high density of carbon nanotubes on the pellicle membrane 119. However, the carbon nanotubes will absorb EUV radiation and because it is desirable for the pellicle membrane 119 to transmit as much EUV radiation as possible, it is also desirable to minimize the amount of carbon nanotubes provided on the pellicle membrane 119.

Taking into account these competing requirements, the amount of carbon nanotubes provided on the pellicle membrane may be such that the carbon nanotubes occupy an area of up to 1% of the pellicle membrane area (or up to 10%). In other words it may be desirable for the reinforcing network (excluding openings or areas between carbon nanotubes) to have an area which is up to 1% (or up to 10%) of the area of the pellicle. The amount of carbon nanotubes as a proportion of the total area may be referred to as the density of the carbon nanotubes. A loss of transmission of the pellicle caused by having carbon nanotubes at a density of more than 10% may have a significant impact on the throughput of the lithographic apparatus. When a density of carbon nanotubes close to 10% (e.g. between 5% and 10%) is used then, if the carbon nanotubes are not evenly distributed across the pellicle membrane, the pellicle membrane may have areas of reduced EUV transmission. Therefore, a density of carbon nanotubes of up to 5% may be preferred, and a density of carbon nanotubes of up to 1% may be more preferred. Although carbon nanotubes may be provided at greater than 1% density, the benefit provided in terms of preventing significant tears of the pellicle is relatively low. This is because the size of a hole formed in the pellicle with carbon nanotubes at 1% density may be limited to such an extent that it does not have a significant effect on patterns projected by the lithographic apparatus (as explained below).

The carbon nanotubes 130 may be provided with a density which forms the reinforcing network such that fully enclosed areas have a maximum dimension of up to 20 microns. The carbon nanotubes may be provided with a lower density, such that the maximum dimension of an enclosed area is greater than 20 microns, for example up to 50 microns or up to 100 microns. However, this will allow holes to form with a maximum dimension of up to 50 microns or up to 100 microns. A disadvantage of such larger hole sizes is that they may cause a significant difference in the intensity of EUV radiation incident upon a substrate being exposed by lithographic apparatus (more EUV radiation passes through the hole than through the pellicle). This may affect the accuracy of the pattern projected onto a substrate by the lithographic apparatus. If the maximum dimension of the enclosed area is limited to up to 20 microns (or in some cases up to 10 microns) then the difference of EUV intensity incident upon a substrate may not be sufficient to significantly affect a pattern being exposed on the substrate. Advantageously this means that the pellicle assembly 115 can continue to be used as normal despite the presence of a hole in the pellicle. The hole will be contained by the reinforcing network and will not significantly affect the performance of the lithographic apparatus. The fully enclosed areas may have an average area of 5 microns or less.

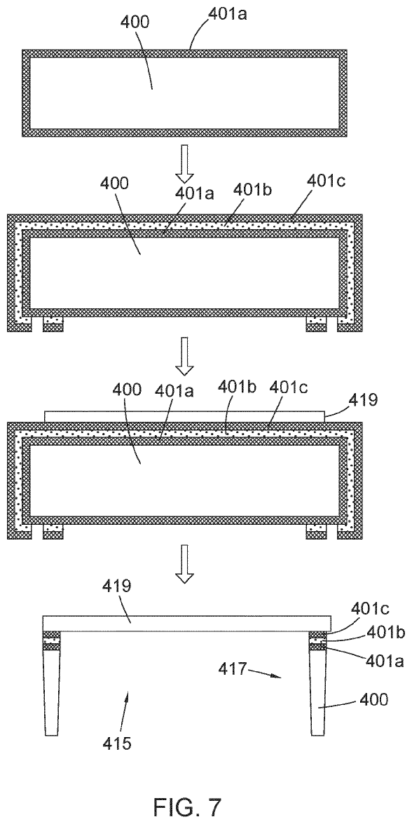

Fabrication of an embodiment of the reinforced pellicle membrane may be as follows. Initial steps of the pellicle fabrication may be as described in further below in connection with FIG. 7. A layer of metal silicide is then deposited (e.g. using sputtering). The layer may be thin, for example less than 5 nanometers. The layer may for example have a thickness of around 2 nanometers (e.g. 2-4 nanometers).

Carbon nanotubes are then provided as a solution in a volatile solvent (e.g. organic solvent quinquethiophene-terminated poly (ethylene glycol). This solution is applied, e.g. by spinning, onto the metal silicide layer. A baking step is then performed to evaporate the solution such that the carbon nanotubes are left behind. This provides a disordered arrangement of carbon nanotubes, as schematically depicted in FIGS. 3A and 3B.

The carbon nanotubes may be single wall nanotubes. The carbon nanotubes may have a diameter of between 0.2 m and 2 nm (this is a typical thickness for a single walled carbon nanotube). The carbon nanotubes may be bundled or not bundled. If the carbon nanotubes are not bundled, then they may have a thickness on the pellicle membrane of up to around 4 nanometers (two nanotubes of 2 nm crossing over each other). However, they may have a thickness of less than this, e.g. 2 nanometers or less, or even 1 nm or less. If the carbon nanotubes are bundled then they may have a bundle thickness of up to 5 nm or even up to 10 nm. This may provide a thickness on the pellicle membrane of up to around 20 nm (two nanotubes of 10 nm crossing over each other).

The carbon nanotubes may for example have a length of 100 microns or more. The carbon nanotubes may have a length of the order of millimeters.

Optionally, a layer of material such as metal may be deposited on top of the carbon nanotubes. This layer may for example be formed using atomic layer deposition.

A second layer of metal silicide is deposited on top of the carbon nanotubes (on top of the optional metal layer if present), e.g. using sputtering. The second layer of metal silicide may be thin, for example having a thickness of 5 nanometers or less. The second layer of metal silicide may for example have a thickness of around 2 nanometers (e.g. 2-4 nanometers).

The pellicle membrane is then cleaned in order to remove any excess carbon nanotubes which may be present, and any other contamination which is present.

An etching process, as set out below in connection with FIG. 7, is then performed.

During the fabrication process, oxidation of each metal silicide layer will remove around 1 nanometer thickness of the metal silicide. It is for this reason that a thickness of around 2 nanometers (e.g. 2-4 nanometers) of metal silicide is used for each layer in this embodiment. The oxidation will add a thickness of around 1 nm of oxidized area to each layer. When the pellicle membrane has been formed, the two layers of metal silicide plus oxidized area may have a combined thickness of around 4 nanometers. The carbon nanotubes will add an additional thickness where they are present (e.g. from around 0.5 nm to up to around 4 nm for non-bundled carbon nanotubes). The resulting pellicle membrane 119 will have a thickness (including carbon nanotubes) of as little as around 5 nanometers or less. The pellicle membrane 119 may have a thickness (including carbon nanotubes) of up to 10 nanometers. The pellicle membrane 119 may have a thickness (including carbon nanotubes) of up to 15 nanometers

The thickness of the carbon nanotubes is not necessarily the thickness of the pellicle membrane as a whole. An area of the pellicle membrane which does not have a carbon nanotube will have a thickness determined by the thickness of the metal silicide layers (including oxidized areas of the metal silicide). The thickness of the pellicle membrane in areas where carbon nanotubes are not present may for example be less than 5 nanometers.

In an embodiment, the average thickness of the pellicle membrane 119 may be less than 5 nanometers. In this context the term “average thickness” includes a contribution to thickness arising from the carbon nanotubes. However, in an embodiment in which the area of the carbon nanotubes is low (e.g. 1% or less of the total area of the pellicle membrane), the contribution of the carbon nanotubes to the average thickness is minimal. This may provide EUV transmission of over 95%. Advantageously the thinness of the pellicle membrane provides higher EUV transmission than conventional pellicle membranes, thereby allowing higher intensity of EUV radiation onto substrates and consequently higher throughput of the lithographic apparatus LA. The density of the carbon nanotubes may be so low (e.g. 1% or less) that transmission of the pellicle membrane is not significantly affected by the carbon nanotubes.

The reinforcing network formed by the carbon nanotubes 130 provides the pellicle membrane 119 with strength. The pellicle membrane 119 may for example be stronger than a conventional metal silicide film of corresponding thickness. The reinforcing network formed by the carbon nanotubes provides strength that allows the thickness of the metal silicide layers to be reduced to a level that would not be possible if the carbon nanotubes were not present.

Carbon nanotubes are reflective for deep ultraviolet (DUV) radiation. Reflection of DUV by the pellicle is undesirable because it may cause unwanted exposure of resist provided on a substrate W in the lithographic apparatus LA. By limiting the amount of carbon nanotubes to e.g. less than 1% of the area of the pellicle membrane, the amount of DUV reflected by the pellicle is also limited. Significant exposure of a wafer by DUV reflected from the pellicle membrane may therefore be avoided.

Although the described embodiment of the invention uses carbon nanotubes to form the reinforcing network, other structures may be used to form the reinforcing network (e.g. boron nanotubes).

Although the described embodiment provides the carbon nanotubes using spin-coating, other methods may be used to provide the carbon nanotubes. Examples of other methods are wet (inkjet) printing, dry printing, spray coating and pressing.

Although sputtering is used to provide the metal silicide layers in the described embodiment, other methods may be used (e.g. atomic layer deposition (ALD). An advantage of using ALD, compared with sputtering, is that no plasma is present. The plasma could potentially damage the carbon nanotubes, and this potential damage is avoided if ALD is used.

Because the carbon nanotubes are coated on both sides by metal silicide, the behavior of the pellicle membrane in terms of outgassing will be the same as for a pellicle membrane formed entirely of metal silicide. This is advantageous because it means that special contamination control methods directed towards carbon nanotubes may not be required.

Advantageously, carbon nanotubes have a small coefficient of thermal expansion (generally smaller than metal silicide), and so sagging of the pellicle membrane which may occur when it is heated may be reduced.

The carbon nanotubes may be coated, for example with Titanium, Zirconium or Tungsten or their oxides (other metals or alloys may be used). Coating of the carbon nanotubes may for example be performed using atomic layer deposition (ALD). Coating the carbon nanotubes may increase the emissivity of the carbon nanotubes, thereby advantageously allowing more effective cooling of the pellicle membrane.

As noted further above, a pellicle assembly is attached to a patterning device MA for use in a lithographic apparatus. The attachment may for example by via an attachment mechanism 22 (see FIG. 2). When attaching the pellicle assembly 15 to the patterning device MA, one or more imaging sensors (e.g. cameras) may be used to monitor the position of the pellicle assembly with respect to the patterning device. A problem which may arise is that the combined reflectivity of the pellicle frame 17 and the pellicle membrane 19 may be very similar to the combined reflectivity of the patterning device MA and the pellicle membrane. The imaging sensor may, as a result, see the same or almost the same intensity of light when looking at the pellicle frame 17 as when looking at the pellicle membrane 19. In other words, the contrast between the pellicle frame and the pellicle membrane (with the patterning device beneath it) may be very low. This may make it difficult to distinguish the pellicle frame, and this in turn may make it difficult to align the pellicle frame with respect to the patterning device so that the pellicle frame can be correctly attached to the patterning device. Embodiments of the invention address this issue.

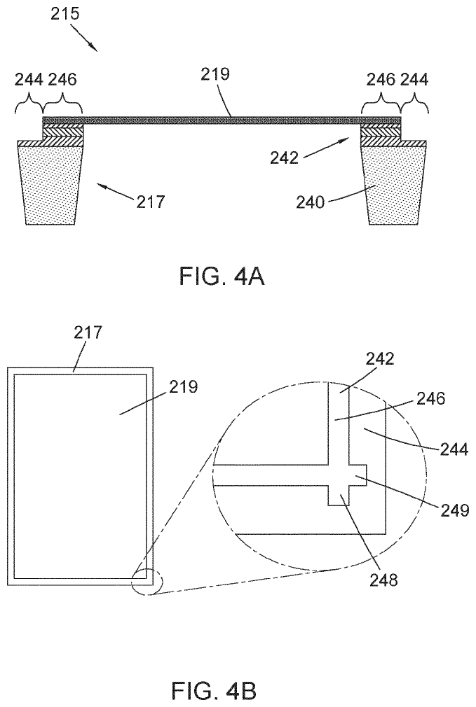

The first embodiment which addresses this issue is schematically depicted in FIG. 4. FIG. 4 is a schematic cross-section of a pellicle assembly 215 according to an embodiment of the invention. The pellicle assembly 215 comprises a pellicle membrane 219 and a frame 217. The frame 217 comprises a base 240 and a stack of layers 242. The stack of layers 242 may be referred to as a border stack. The base 240 of the frame 217 may be formed for example from silicon. The border stack 242 may for example be formed from a combination of silicon oxide layers and silicon based layers (an example is described further below). As noted further above, the pellicle membrane 219, border stack 242 and base 240 may provide a combined reflectivity which is similar to the combined reflectivity of the pellicle membrane 219 and a patterning device (not depicted). This may cause difficulty in aligning the pellicle assembly to the patterning device. In the embodiment of FIG. 4, an outer portion of part of the border stack has been partially removed (e.g. via etching). As a result, the border stack 242 and pellicle membrane 219 do not extend fully to an outer edge of the frame 217. Instead, there is a step downwards of the border stack (and pellicle membrane 219) before the outer edge of the frame 217. An imaging system looking at the pellicle assembly 215 will, due to the absence of part of the border stack 242, see a different reflectivity at the outer periphery of the pellicle assembly 215. This is because light is reflected by only the remaining portion of the border stack (in this case some silicon oxide) and the base 240, and is not reflected by the rest of the border stack 242 or the pellicle membrane 219. A significant contrast is thereby achieved between an outer portion 244 of the pellicle frame 217 and an inner portion 246 of the pellicle frame 217. This contrast between the inner portion 246 and the outer portion 244 of the pellicle frame 217 allows the pellicle frame to be more easily identified by the imaging system used to align the pellicle assembly 215 to a patterning device. In addition, the difference in contrast allows the pellicle assembly 215 to be more easily distinguished from the patterning device. This allows alignment of the pellicle assembly 215 to the patterning device to be achieved more easily.

FIG. 4B schematically depicts from above a pellicle assembly 215 according to an embodiment of the invention. As with the embodiment depicted in 4A, the pellicle assembly 215 comprises a pellicle membrane 219 and a frame 217. An enlarged view of one corner of the pellicle assembly 215 is also shown in FIG. 4B. This enlarged view shows the pellicle membrane 219, an inner portion 246 of the pellicle frame and an outer portion 244 of the pellicle frame. The inner portion 246 includes a full border stack 242 of layers (as depicted in FIG. 4A), but in the outer portion 244 at least some of the border stack layers are not present. At least some border stack layers may for example having been etched away from the outer portion 244 of the pellicle frame 217.

The full border stack 242 does not form a simple corner. Instead, portions of the full border stack 242 extend beyond a point at which the full border stacks meet, and thereby form two projections 248, 249 which extend from the corner. The projections 248, 249 extend perpendicularly to each other. These projections 248, 249 advantageously may be used as an alignment mark by an alignment system which is configured to align the pellicle assembly 215 to a patterning device (not depicted). The alignment system may include an imaging system (e.g. camera) and may be configured to look for the projections 248, 249 when determining the position of the pellicle assembly 215. The difference between the reflectivity of the inner portion 246 and the outer portion 244 of the pellicle frame 217 may be known, and thus the contrast that will be seen by the alignment system may be also be known by the alignment system. This may allow the alignment system to more easily identify the alignment mark formed by the projections 248, 249.

Although two perpendicular projections 248, 249 of the inner portion 246 of the border stack 242 are depicted in FIG. 4B, other shapes may be formed. A shape or shapes may be formed at one or more corners of the pellicle frame and/or may be formed elsewhere on the pellicle frame.

The projections, or other shape, of the inner portion 246 of the border stack advantageously make it easier for an alignment system to align the pellicle assembly with a patterning device.

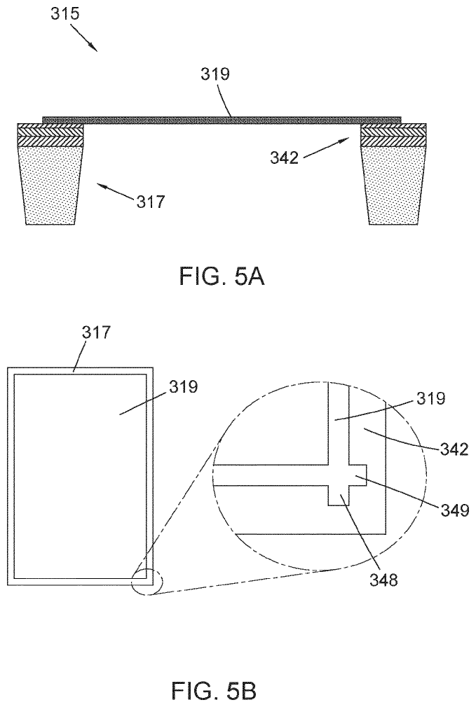

FIG. 5 depicts a pellicle assembly 315 according to a further embodiment of the invention. In this embodiment, the border stack 342 extends fully to the outer edge of the pellicle frame 317. However, the pellicle membrane 319 does not extend fully to the outer edge of the pellicle frame 317 (part of the pellicle membrane may be removed e.g. by etching). As a result, there is a transition between the pellicle membrane 319 and the border stack 342. This transition provides a difference of reflectivity which may be used by an alignment system to determine the position of the pellicle assembly 315.

FIG. 5B depicts the pellicle assembly 315 viewed from above. In this embodiment, the border stack 342 extends fully to the outer edge of the pellicle frame 317, but the pellicle membrane 319 does not. A corner of the pellicle membrane includes two projections 348, 349. These projections may be used as an alignment mark in the same way as described above in connection with the previous embodiment.

Although two perpendicular projections 348, 349 of the pellicle membrane 319 are depicted in FIG. 5B, other shapes may be formed. A shape or shapes may be formed at one or more corners of the pellicle frame and/or may be formed elsewhere on the pellicle frame. The projections, or other shape, of the pellicle membrane 319 advantageously make it easier for an alignment system to align the pellicle assembly with a patterning device.

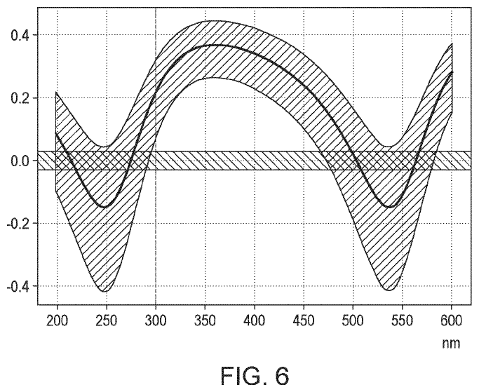

In an embodiment, the thickness of the border stack of a pellicle assembly may be selected in order to ensure that the combined reflectivity of the pellicle membrane, border stack and base is significantly different to the combined reflectivity of the pellicle membrane and a patterning device. FIG. 6 is a graph which shows an example of how the contrast ratio will change as a function of the thickness of the border stack. The contrast ratio is indicated on the vertical axis and the border stack thickness is indicated on the horizontal axis. The graph was generated using optical modelling software for a border stack comprising silicon and silicon oxide. The dark line depicts the modelled optical reflectivity at an exact target thicknesses of the border stack. The bands either side of the dark line represent the variation in reflectivity that will be caused if there is variation in layer thicknesses during fabrication of the border stack. As may be seen from FIG. 6, for some thicknesses of the border stack, the contrast ratio may be low and may even be zero. For other thicknesses, the contrast ratio may be high (e.g. 0.2 or more). Modelling software may be used to select the thickness of the border stack to ensure that a contrast ratio of more than 0.01 (e.g. more than 0.02) is provided. A contrast ratio of 0.2 or more may be obtained. A contrast ratio of 0.01 or more may allow discrimination of the pellicle assembly from the patterning device. However, to provide a margin of error a contrast ratio of 0.02 or more is preferable. In some instances there may be variation of layer thicknesses, and this will affect the contrast ratio. For this reason, a contrast ratio of 0.1 or more, or 0.2 or more may be used, in order to ensure that the contrast remains good even if there are layer thickness variations.

The contrast ratio may be adjusted via selection of materials with different refractive indices. For example, a sacrificial layer of the border stack may be formed from a material which has a desirable refractive index from a stack reflectivity point of view. In another example, because silicon and silicon oxide have different refractive indices, changing a ratio between silicon and silicon oxide in the border stack will change the refractive index of the stack.

A pellicle assembly according to an embodiment of the invention may be formed using physical vapor deposition (PVD)

The applicant has developed a manufacturing process wherein pellicles with metal silicide or doped metal silicide pellicle layers may be manufactured with a desired quality and yield. The manufacturing process is described below.

It should be noted that, as with other figures in this document, the figures are intended to be illustrative and are, as such, not drawn to scale. This is of particular importance when considering the thickness of, for example, pellicle layers with respect to, for example, the planar substrate. This is also of particular importance when considering the stages of manufacturing. Key stages of manufacture are shown, although it should be understood that these are illustrative in nature and additional steps and processes may take place before, during, between, and/or after the steps as shown. Additionally, some stages may be illustrated as a single step (e.g. an etch process) but may in fact be performed as several sequential smaller processes with the overall effect illustrated by the single step.

The processes below and above refer to etching. Etching is a common manufacturing process used to remove portions of material. In multi-layered materials, selective etching can remove a portion of an outer layer such that an underlying layer is exposed. Etching may comprise providing a resist, for example a photoresist, and patterning the resist. Embodiments are not particularly limited by the nature of the resist and any suitable resist may be used. The resist serves to protect the underlying layers from etching. As such, the patterning of the resist serves to define the areas of the stack which are removed by a subsequent etching step. The etchant may be a chemical etchant, such as, for example, phosphoric acid and/or hydrofluoric acid.

FIG. 7 schematically illustrates stages of manufacture of a pellicle assembly 415 according to an embodiment of the invention. A planar substrate 400 is provided, which may be referred to simply as a substrate 400. The substrate 400 may be, for example, a silicon wafer. The substrate 400 has a shape such as a square, a circle or a rectangle, for example. The shape of the substrate 400 is not particularly limited, but is most likely circular as this is the most commonly available shape. The size of the substrate 400 is not particularly limited.

A first sacrificial layer 401a is provided, for example by depositing it on the substrate 400. The first sacrificial layer 401a preferably substantially surrounds the substrate 400, but in some embodiments it may only partially surround the substrate 400. The first sacrificial layer 401a comprises an oxide, for example silicon oxide or a thermal oxide.

A second sacrificial layer 401b is then provided, for example by depositing it on the first sacrificial layer 401a. The second sacrificial layer 401b preferably substantially surrounds the first sacrificial layer 401a, but in some embodiments it may only partially surround the first sacrificial layer 401a. The second sacrificial layer 401b comprises a type of silicon, for example polysilicon or doped silicon, preferably in-situ doped polysilicon (ISDP). Advantageously, a second sacrificial layer 401b comprising ISDP can be formed with relatively low roughness and few protrusions.

Adjacent sacrificial layers (e.g. the first and second sacrificial layers 401a, 401b) formed from different materials (in this instance an oxide and silicon) will etch at different rates for a given etching operation. That is, for a specific etching operation, the first sacrificial layer 401a may etch quickly whereas the second sacrificial layer 401b may etch comparatively slowly or not at all. In this way, adjacent sacrificial layers formed from different materials can advantageously cause one layer to form an etch stop for a given etching operation.

A third sacrificial layer 401c is provided, for example by depositing it on the second sacrificial layer 401b. The third sacrificial layer 401c preferably substantially surrounds the second sacrificial layer 401b, but in some embodiments it may only partially surround the second sacrificial layer 401b. The third sacrificial layer 401c comprises a thin layer of an oxide, for example a silicon oxide or thermal oxide. By thin, it is meant that the thickness of the third sacrificial layer 401c is of the same order (or thinner) as the thickness of the pellicle membrane 419. The third sacrificial layer 401c may be known as a thin oxide layer 401c. Thin layers of oxide are easily grown with a well-known layer thickness as is known in the art. As such, a thin oxide layer 401c may be formed with low surface roughness. Hence this provides a smooth surface upon which to deposit the pellicle membrane 419.

The substrate 400 and the first, second and third sacrificial layers 401a, 401b, 401c may be referred to at this stage as a stack.

Prior to depositing the pellicle membrane, the sacrificial layers 401a, 401b, 401c are patterned in order to define an area which will subsequently become the border, thereby defining the shape of the ultimate pellicle assembly. That is, a face of the stack is patterned in order to define the shape of the ultimate pellicle assembly. This face may be referred to as the ‘back’ of the stack, defined as the opposite face to that which will receive the pellicle membrane 419. This process may be known as a patterning process. This patterning process may be performed using any suitable resist and etch process. During this process, the substrate may be handled by equipment, for example it may be clamped in place and/or inverted. Such handling may risk damaging or contaminating one or more surfaces of the substrate or associated sacrificial layers. By performing this patterning process prior to depositing the pellicle membrane 419, the risk of damage to the pellicle membrane 419 may be reduced. A particular pattern is depicted in FIG. 7, but it should be understood that any alternative pattern may be produced depending on the desired final shape of the pellicle assembly.

Following the patterning process, a pellicle membrane 419 is provided on a face of the third sacrificial layer 401c. The pellicle membrane 19 may comprise one or more pellicle layers. The pellicle membrane 419 shown in FIG. 7 comprises a single pellicle layer. The pellicle layer comprises doped metal silicide, some of the benefits of which are discussed above. The pellicle layer in this embodiment, or in other embodiments, may alternatively comprise metal silicide. The pellicle membrane 419 may comprise multiple layers. The pellicle membrane 419 may comprise a reinforcing network (for example formed from carbon nanotubes). The reinforcing network may be embedded in metal silicide of the pellicle membrane. The reinforcing network may be located between layers of metal silicide. The pellicle membrane 419 may be as described further above in connection with other embodiments.

One or more capping layers may be provided with the pellicle layer. These capping layers may be provided as an etch stop for future etching processes. Alternatively or in addition, these capping layers may be provided so as to control the amount of stress on the pellicle layer or pellicle membrane. The capping layer may for example comprise an oxide. The capping layer may beneficially be deposited with a stress comparable to the stress of the third sacrificial layer 401c. The capping layer may beneficially be configured so as to have a similar etch time to the third sacrificial layer 401c.

After deposition of the pellicle membrane 419, further portions of the substrate 400, first sacrificial layer 401a, second sacrificial layer 401b and third sacrificial layer 401c may be selectively back-etched to remove a portion of the substrate 400 (and portions of the sacrificial layers 401a, 401b, 401c) and leave only an outer perimeter to form the frame 417 to support the pellicle membrane 419.

A first etching step consists of performing a deep Si-etch of the substrate 402, which may be a wafer having a thickness of around 700 um. This etch may be performed in a wet etch chemistry and it may require a long period of time to be completed (compared with other etches which are for thinner layers). Once the etchant reaches the first sacrificial layer 401a (which is an oxide), the etch-rate slows down significantly. A significant over-etch may be used to make sure that the Si from the wafer is completely removed inside the cavity area. This over etch is possible because the first sacrificial layer 401a is an oxide layer and thus acts as an etch barrier, protecting the rest of the layers that are on top of it.

In a next step, the first sacrificial layer 401a is removed using a different wet etch chemistry. The etch is highly selective to the first sacrificial layer 401a, and does not significantly etch the second sacrificial layer 401b (the second sacrificial layer, which is silicon, acts as an etch stop layer).

Subsequent to this, the second sacrificial layer 401b, which is silicon, is removed by a wet etch which is highly selective to the second sacrificial layer. The etch does not significantly etch the third sacrificial layer 401c (the third sacrificial layer, which is oxide, acts as an etch stop layer).

Finally the third sacrificial layer 401c is removed by a wet etch until the pellicle membrane 419 is reached. Because the third sacrificial layer 401c is thinner than, for example, the second sacrificial layer 401b, the etch takes place over a shorter period of time. This means that the etching time can be more closely controlled, thereby minimizing the risk of etching into the pellicle membrane 419.

The third sacrificial layer 401c acts as a diffusion barrier between the second sacrificial layer 401b and the pellicle membrane 419. The third sacrificial layer may be formed by oxidizing the second sacrificial layer. Alternatively, the third sacrificial layer 401c may be formed using a deposition method such as PVD, PECVD or ALD.

The frame 417 comprises a portion of the substrate 400, and a border stack comprising a portion of the first sacrificial layer 401a, a portion of the second sacrificial layer 401b and a portion of the third sacrificial layer 401c.

In an example given some of the materials discussed above with reference to this embodiment, the frame 417 may comprise an ordered stack of silicon, an oxide, ISDP, and a thin oxide, before coming into abutment with a doped metal silicide pellicle membrane. Alternatively, the frame 417 may comprise an ordered stack of silicon, an oxide, silicon, and a thin oxide, before coming into abutment with a doped metal silicide pellicle membrane. It should be understood that, depending on the number of sacrificial layers and the composition thereof, the frame 417 may comprise a corresponding ordered stack of layers.

The choice of composition of sacrificial layers may additionally aid in reducing the processing time of a pellicle assembly. For example, some processes constitute ‘bottle-necks’ in the manufacturing process, e.g. the formation of silicon nitride or ISDP. Beneficially these materials may be omitted from some embodiments of the invention, thereby reducing the processing time.

The choice of composition of sacrificial layers and/or the thickness of the sacrificial layers, may be selected based upon the reflectivity of the resulting border stack and frame, as explained further above. The reflectivity may be selected such that it is significantly different to the combined reflectivity of the pellicle membrane and a patterning device (e.g. providing a contrast ratio of 0.1 or more, or other contrast ratios as discussed further above). In one example, the third sacrificial layer 401c, which may be a layer of an oxide, for example a silicon oxide or thermal oxide, may have a thickness which is selected to provide a desired reflectivity of the border stack and frame. In another example, the first sacrificial layer 401a (or second sacrificial layer 401b) may have a thickness which is selected to provide a desired reflectivity of the border stack and frame. The first sacrificial layer is thickest, and as a result it may be easiest to achieve a desired change of reflectivity via modification of the first sacrificial layer.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A pellicle membrane for a lithographic apparatus, wherein the pellicle membrane comprises metal silicide and a reinforcing network.

2. The pellicle membrane of claim 1, wherein the reinforcing network is located between metal silicide layers.

3. The pellicle membrane of claim 1, wherein the reinforcing network is irregular.

4. The pellicle membrane of claim 1, wherein the reinforcing network includes windows with a maximum dimension of up to 20 microns.

5. The pellicle membrane of claim 1, wherein the reinforcing network includes windows having an average size of at least 5 microns.

6. The pellicle membrane of claim 1, wherein the reinforcing network, excluding windows in the reinforcing network, has an area which is up to 10% of the pellicle.

7. The pellicle membrane of claim 1, wherein the reinforcing network is formed from nanotubes.

8. The pellicle membrane of claim 7, wherein the nanotubes are carbon nanotubes.

9. The pellicle membrane of claim 7, wherein the nanotubes are coated.

10. The pellicle membrane of claim 1, wherein an additional layer is provided between the reinforcing network and at least one layer of the metal silicide layers.

11. The pellicle membrane of claim 10, wherein the additional layer is a metallic layer.

12. The pellicle membrane of claim 1, wherein the metal silicide is nitridated metal silicide.

13. A pellicle assembly comprising the pellicle membrane of claim 1 and a frame, the pellicle membrane being supported by the frame.

14.-24. (canceled)

25. The pellicle assembly according to claim 13, wherein the frame comprises a base and a border stack, and wherein the border stack comprises an oxide layer located below the pellicle membrane and above a silicon-based layer of the border stack.

26. The pellicle assembly of claim 25, wherein the oxide layer has a thickness which is selected to contribute to a desired contrast ratio between a combination of the pellicle membrane and pellicle frame and a combination of the pellicle membrane and a patterning device.

27. The pellicle assembly of claim 26, wherein the desired contrast ratio is 0.1 or more.

28. A mask assembly comprising the pellicle assembly of claim 13 and further comprising a lithographic mask, wherein a border stack and the pellicle membrane have a combined reflectivity which is different to a combined reflectivity of the pellicle membrane and the lithographic mask.

29. The mask assembly of claim 28, wherein the combined reflectivity of the border stack and pellicle membrane versus the combined reflectivity of the pellicle membrane and lithographic mask provides a contrast ratio of 0.1 or more.

30. A method of fabricating a pellicle assembly, the method comprising:
providing a first metal silicide layer on an uppermost sacrificial layer on a base of the pellicle assembly;
providing a reinforcing network on the first metal silicide layer; and
providing a second metal silicide layer on the reinforcing network.

31. The method of claim 30, wherein a metallic layer is provided on top of the reinforcing network before the second metal silicide layer is provided.

32.-33. (canceled)
